(19) United States
(12) Patent Application Publication
(10) Pub. No.: US 2010/0164373 A1
(43) Pub. Date: Jul. 1, 2010

(54) ORGANIC ELECTROLUMINESCENCE DEVICE AND PRODUCTION METHOD THEREOF

(75) Inventor: Yoshihiro KOBAYASHI, Tokyo-to (JP)

Correspondence Address: LADAS & PARRY LLP, 224 SOUTH MICHIGAN AVENUE, SUITE 1600, CHICAGO, IL, 60604, US

(73) Assignee: DAI NIPPON PRINTING CO., LTD., Tokyo-to (JP)

(21) Appl. No.: 12/641,600

(22) Filed: Dec. 18, 2009

(30) Foreign Application Priority Data
Dec. 26, 2008 (JP) 2008-333998

(51) Int. Cl. H01J 1/62; H01J 9/02

(52) U.S. Cl. 313/504; 445/35

(57) ABSTRACT

An object of the present invention is to provide an organic EL device with a fine appearance at the time of non-light emission, and a production method thereof. The object is achieved by providing an organic EL device comprising: a substrate, a transparent electrode layer formed on the substrate, an organic EL layer including a light emitting layer, formed on the transparent electrode layer, and a metal electrode layer including a first metal film and a second metal film, formed on the organic EL layer, wherein the metal electrode layer comprises: a first electrode region with the first metal film disposed to face the organic EL layer side, and a second electrode region with the second metal film disposed to face the organic EL layer side, and wherein the first electrode region and the second electrode region have different reflection characteristics, and the first metal film of the first electrode region and the second metal film of the second electrode region contact electrically.

### FIELD OF THE INVENTION

The present invention relates to a passive type organic electroluminescence device and a production method thereof.

### DESCRIPTION OF THE RELATED ART

As the organic electroluminescence (hereafter, “electroluminescence” may be abbreviated to “EL”) device, a structure having an organic EL layer comprising a light emitting layer disposed between a transparent electrode layer and a metal electrode layer (it is also referred to as a back side electrode layer) is known.

According to such an organic EL device, since the metal electrode layer has a metallic luster, it is visually observed as a mirror surface due to external light reflection at the time of non-light emission. Therefore, it may spoil the appearance or the design of an appliance utilizing the organic EL device.

Moreover, in the case of light emission display with a light emitting pattern formed as a fixed pattern, if the light emitting pattern is formed by producing a metal electrode layer in a pattern, the light emitting pattern is observed visually at the time of non-light emission.

In view of this, a method of forming a light emitting pattern by forming an insulating layer in a pattern has been proposed instead of a method of forming the metal electrode layer in a pattern (see Japanese Patent Application Laid-Open No. 10-284254). However, in this case, for producing a plurality of organic EL devices having fixed patterns different with each other, the pattern design of the insulating layers should be changed for each pattern so as to increase the production cost.

### SUMMARY OF THE INVENTION

### Problem to be solved by the Invention

The present invention has been achieved in view of the circumstances mentioned above, and a main object thereof is to provide an organic EL device with a fine appearance at the time of non-light emission, and a production method thereof.

### Means for Solving the Problems

In order to achieve the object, the present invention provides an organic EL device comprising: a substrate, a transparent electrode layer formed on the substrate, an organic EL layer including a light emitting layer, formed on the transparent electrode layer, and a metal electrode layer including a first metal film and a second metal film, formed on the organic EL layer, wherein the metal electrode layer comprises: a first electrode region with the first metal film disposed to face the organic EL layer side, and a second electrode region with the second metal film disposed to face the organic EL layer side, and wherein the first electrode region and the second electrode region have different reflection characteristics, and the first metal film of the first electrode region and the second metal film of the second electrode region contact electrically.

According to the present invention, since the first electrode region and the second electrode region have different reflection characteristics, a pattern shape formed with the first electrode region and the second electrode region can be observed visually at the time of non-light emission. On the other hand, at the time of light emission, a pattern shape different from the pattern shape formed with the first electrode region and the second electrode region can be displayed. Therefore, a desired pattern can be displayed by light emission at the time of light emission, and a predetermined pattern can be observed visually at the time of non-light emission so that an organic EL device with a preferable appearance at the time of non-light emission is provided.

In the invention, it is preferable that the first metal film and the second metal film contain the same metal element. In this case, by changing a factor such as the oxygen amount included in the first metal film and the second metal film, the first metal film and the second metal film can have a different reflectance.

In this case, it is preferable that the metal element is aluminum because aluminum has high reflectance.

In the present invention, it is preferable that the reflectance of the first electrode region is lower than the reflectance of the second electrode region. It is also preferable that the first electrode region and the second electrode region have different colors of reflected lights. In these cases, the pattern shape formed by the first electrode region and the second electrode region is observed easily at the time of non-light emission.

Moreover, in the present invention, it is preferable that the first metal film and the second metal film are laminated successively on the organic EL layer in the first electrode region, and the second metal film is formed on the organic EL layer without formation of the first metal film in the second electrode region. According to such a configuration, the second metal film is formed easily.

Furthermore, the first metal film and the second metal film may be laminated successively on the organic EL layer in the first electrode region; and the second metal film, the first metal film, and the second metal film may be laminated successively on the organic EL layer in the second electrode region.

Moreover, the first metal film may be formed on the organic EL layer in the first electrode region without formation of the second metal film, and the second metal film may be formed on the organic EL layer in the second electrode region without formation of the first metal film.

Moreover, the present invention provides a production method of an organic EL device comprising a metal electrode layer forming step which further comprises a first metal film forming step and a second metal film forming step, wherein the first metal film forming step is for forming a first metal film and includes: a first metal film forming layer forming step for forming a first metal film forming layer in a pattern in vacuum on a substrate with a transparent electrode layer and an organic EL layer including a light emitting layer laminated successively, and an exposing step of exposing the first metal film forming layer to atmosphere including oxygen; the second metal film forming step is for forming a second metal film in vacuum onto the entire surface of the substrate with the first metal film formed in the pattern; and the metal electrode layer forming step is for forming a metal electrode layer which comprises: a first electrode region with the first metal film disposed to face the organic EL layer side, and a second electrode region with the second metal film disposed to face the organic EL layer side.

According to the present invention, since the exposing step of exposing the first metal film forming layer to the atmosphere including oxygen is carried out in the first metal film forming step, a first metal film and a second metal film having different reflection characteristics can be obtained. Thereby, a first electrode region and a second electrode region having different reflection characteristics can be formed. Therefore, as mentioned above, a desired pattern can be displayed at the time of light emission, and a predetermined pattern can be observed visually at the time of non-light emission so that an organic EL device with preferable appearance at the time of non-light emission can be produced.

Furthermore, the present invention provides a production method of an organic EL device comprises a metal electrode layer forming step which further comprises a first-second metal film forming step, a first metal film forming step, and a second-second metal film forming step, wherein the first-second metal film forming step is for forming a second metal film in a pattern in vacuum on a substrate with a transparent electrode layer and an organic EL layer including a light emitting layer laminated successively; the first metal film forming step is for forming a first metal film and includes a first metal film forming layer forming step of forming a first metal film forming layer in vacuum on the entire surface of the substrate with the second metal film formed, and an exposing step of exposing the first metal film forming layer to the atmosphere including oxygen; the second-second metal film forming step is for forming a second metal film in vacuum on the entire surface of the substrate with the second metal film and the first metal film formed; and the metal electrode layer forming step is for forming a metal electrode layer which comprises: a first electrode region with the first metal film disposed to face the organic EL layer side, and a second electrode region with the second metal film disposed to face the organic EL layer side.

According to the present invention, since the exposing step of exposing the first metal film forming layer to the atmosphere including oxygen is carried out in the first metal film forming step, a first metal film and a second metal film having different reflection characteristics can be obtained. Thereby, a first electrode region and a second electrode region having different reflection characteristics can be formed. Therefore, as mentioned above, a desired pattern can be displayed at the time of light emission, and a predetermined pattern can be observed visually at the time of non-light emission so that an organic EL device with preferable appearance at the time of non-light emission can be produced.

In the invention, the first metal film with a plurality of layers laminated may be formed by repeating the first metal film forming layer forming step and the exposing step in the first metal film forming step. Thereby, a first metal film having desired reflection characteristics can be formed.

Moreover, in the present invention, it is preferable to form a film of the same metal in the first metal film forming step and the second metal film forming step. In this case, by controlling the degree of oxidation of the first metal film in the exposing step, the reflectance of the first metal film can be adjusted so that the first metal film and the second metal film having different reflectances can be formed.

In this case, it is preferable that the metal is aluminum because aluminum has high reflectance.

### EFFECTS OF THE INVENTION

In the present invention, since the first electrode region and the second electrode region have different reflection characteristics, the effect of providing preferable appearance at the time of non-light emission can be achieved by enabling visual observation of the pattern shape formed by the first electrode region and the second electrode region at the time of non-light emission.

### BRIEF DESCRIPTION OF THE DRAWINGS

FIG. 1 is a diagram of an example of an organic EL device of the present invention;

FIG. 2 is another diagram of the example of an organic EL device of the present invention;

FIG. 3 is a cross-sectional view taken on the line A-A of FIG. 1;

FIGS. 4A and 4B are diagrams of an example of an organic EL device of the present invention at the time of light emission and non-light emission;

FIGS. 5A and 5B are diagrams of another example of an organic EL device of the present invention at the time of light emission and non-light emission;

FIG. 6 is a schematic cross-sectional view of another example of an organic EL device of the present invention;

FIG. 7 is a diagram of another example of an organic EL device of the present invention;

FIG. 8 is a cross-sectional view taken on the line B-B of FIG. 7;

FIG. 9 is a schematic cross-sectional view of another example of an organic EL device of the present invention;

FIG. 10 is a schematic cross-sectional view of yet another example of an organic EL device of the present invention;

FIGS. 11A to 11D are a step diagram showing an example of a production method of an organic EL device of the present invention;

FIGS. 12A to 12D are a step diagram showing an example of the first metal film forming step in a production method of an organic EL device of the present invention; and

FIGS. 13A to 13E are a step diagram showing another example of a production method of an organic EL device of the present invention.

### DESCRIPTION OF THE PREFERRED EMBODIMENTS

Hereinafter, an organic EL device of the present invention and a production method thereof will be explained in detail.

A. Organic EL device

First, an organic EL device of the present invention will be explained.

The organic EL device of the present invention comprises: a substrate, a transparent electrode layer formed on the substrate, an organic EL layer including a light emitting layer, formed on the transparent electrode layer, and a metal electrode layer including a first metal film and a second metal film, formed on the organic EL layer, wherein the metal electrode layer comprises: a first electrode region with the first metal film disposed to face the organic EL layer side, and a second electrode region with the second metal film disposed to face the organic EL layer side, and wherein the first electrode region and the second electrode region have different reflection characteristics, and the first metal film of the first electrode region and the second metal film of the second electrode region contact electrically.

The organic EL device of the present invention will be explained with reference to the drawings.

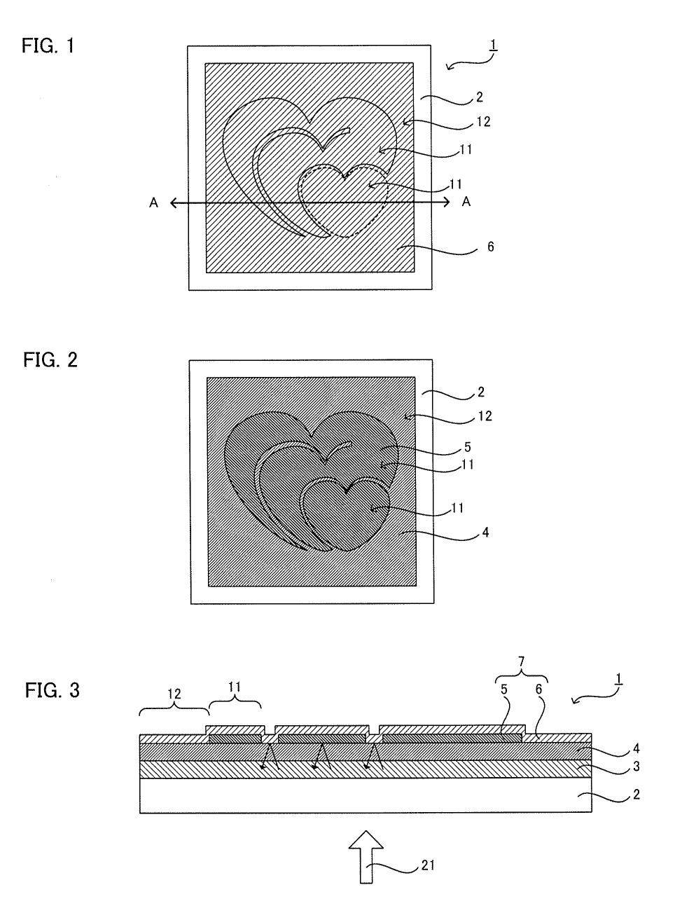

FIG. 1 is a top view of an example of an organic EL device of the present invention, FIG. 2 is a diagram with the second metal film omitted from FIG. 1, and FIG. 3 is a cross-sectional view taken on the line A-A of FIG. 1.

The organic EL device 1 shown in FIGS. 1 to 3 comprises: a substrate 2, a transparent electrode layer 3 formed on the substrate 2, an organic EL layer 4 formed on the transparent electrode layer 3, and a metal electrode layer 7 including a first metal film 5 and a second metal film 6, formed on the organic EL layer 4. The metal electrode layer 7 comprises: a first electrode region 11 with the first metal film 5 disposed to face the organic EL layer 4 side, and a second electrode region 12 with the second metal film 6 disposed to face the organic EL layer 4 side. The first metal film 5 constituting the first electrode region 11 and the second metal film 6 constituting the second electrode region 12 are disposed to contact electrically. Moreover, the first electrode region 11 and the second electrode region 12 have different reflection characteristics.

According to such an organic EL device, as shown in FIG. 3, at the time of non-light emission, external light 21 is reflected on the surface of the first metal film 5 and the second metal film 6. As mentioned above, the first electrode region 11 and the second electrode region 12 have different reflection characteristics.

For example, in the case the reflectance of the first electrode region 11 is lower than the reflectance of the second electrode region 12, the first electrode region 11 serves as a low reflection region, and the second electrode region 12 as a high reflection region so that at the time of non-light emission, a pattern shape formed by the first electrode region 11 and the second electrode region 12 can be observed visually.

Furthermore, also in the case the colors of the reflected lights of the first electrode region 11 and the second electrode region 12 are different with each other, a pattern shape formed by the first electrode region 11 and the second electrode region 12 can be observed visually at the time of non-light emission. Specifically, in the case the first metal film 5 is made of gold and the second metal film 6 is made of aluminum, since the first electrode region 11 has a gold color and the second electrode region 12 has a silver color, the colors of the reflected lights in the first electrode region 11 and the second electrode region 12 are different with each other. Thus, at the time of non-light emission, a pattern shape formed by the first electrode region 11 and the second electrode region 12 can be observed visually. Moreover, in the case the first metal film 5 is made of aluminum and the second metal film 6 is made of indium zinc oxide (IZO), the first electrode region 11 has a silver color and the second electrode region 12 permits light transmission so as to be colorless and transparent. Thus, a light beam is reflected only in the first electrode region 11. Accordingly, the colors of the reflected lights in the first electrode region 11 and the second electrode region 12 are different with each other so that a pattern shape formed by the first electrode region 11 and the second electrode region 12 can be observed visually at the time of non-light emission.

Therefore, by providing the first electrode region and the second electrode region in a predetermined pattern shape, characters, graphics, and the like, can be observed visually at the time of non-light emission.

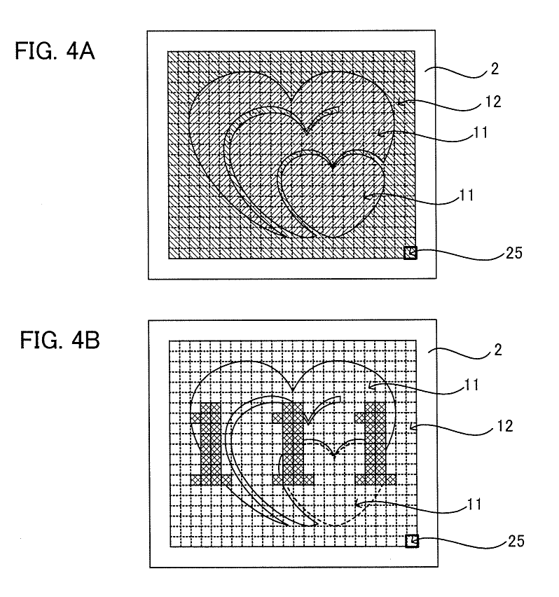

The organic EL device of the present invention is in general of a passive type with the transparent electrode layer and the metal electrode layer formed like stripes so as to be crossed with each other. According to the passive type organic EL device, intersections of the transparent electrode layer in stripe form and the metal electrode layer in stripe form are selected and illuminated when it is driven. In this case, as shown in FIGS. 4A and 4B, as to a pixel 25, as mentioned above, a pattern shape formed by the first electrode region 11 and the second electrode region 12 can be observed visually at the time of non-light emission (FIG. 4A). On the other hand, at the time of light emission, by selecting a predetermined pixel 25, a pattern shape (“111” in the example shown in FIG. 4B) different from the pattern shape formed by the first electrode region 11 and the second electrode region 12 can be displayed by light emission (FIG. 4B).

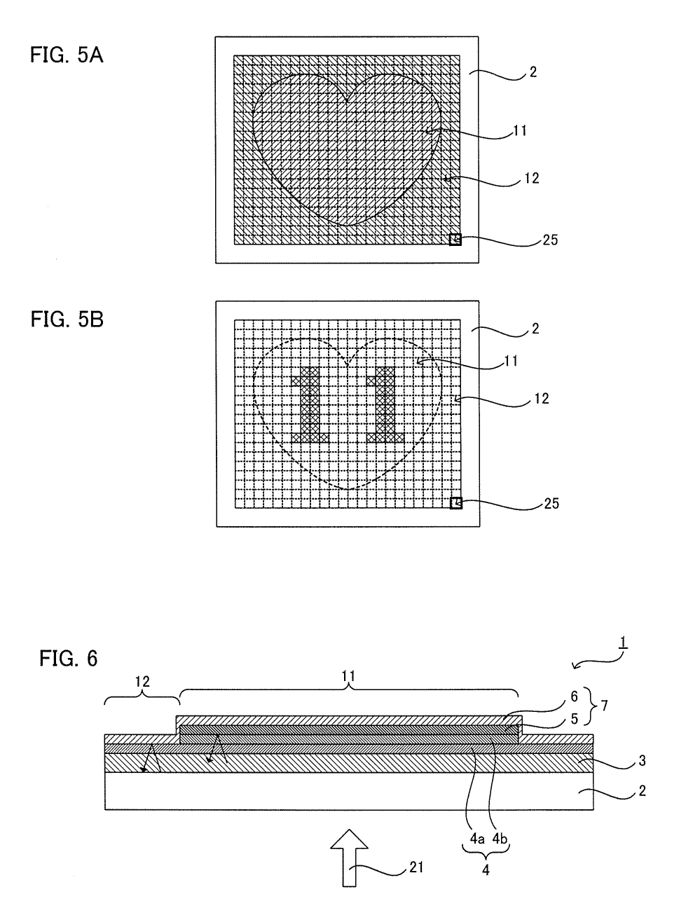

Moreover, only the first electrode region or only the second electrode region may be provided as a region enabling the light emission display. In the example shown in FIGS. 5A and 5B, only the first electrode region 11 is provided as a region enabling the light emission display. At the time of non-light emission, the pattern shape formed by the first electrode region 11 and the second electrode region 12 can be observed visually (FIG. 5A). On the other hand, at the time of light emission, by selecting a predetermined pixel 25, a pattern shape (“11” in the example shown in FIG. 5B) different from the pattern shape formed by the first electrode region 11 and the second electrode region 12 can be displayed in the first electrode region 11 by light emission (FIG. 5B).

For example as shown in FIG. 6, in the case the organic EL layer 4 includes a light emitting layer 4b and an electron injecting layer 4b laminated with the electron injecting layer 4b formed only in the first electrode region 11, charge is injected easily only to the light emitting layer 4a of the first electrode region 11 with the electron injecting layer 4b formed so as to generate the charge transfer difference between the first electrode region 11 and the second electrode region 12. Thus, only the first electrode region 11 is provided as a region enabling the light emission display.

Therefore, also in the case of providing only the first electrode region or only the second electrode region as a region enabling the light emission display, a pattern shape different from a pattern shape formed by the first electrode region and the second electrode region can be displayed by light emission.

According to the present invention, a desired pattern can be displayed by light emission at the time of light emission and a predetermined pattern can be observed visually at the time of non-light emission so that an organic EL device with a preferable appearance at the time of non-light emission can be provided.

Hereinafter, each configuration in the organic EL device of the present invention will be explained.

### 1. Metal Electrode Layer

A metal electrode layer used in the present invention is formed on an organic EL layer and includes a first metal film and a second metal film. The metal electrode layer comprises a first electrode region with the first metal film disposed to face the organic EL layer side, and a second electrode region with the second metal film disposed to face the organic EL layer side. The first electrode region and the second electrode region have different reflection characteristics, and the first metal film of the first electrode region and the second metal film of the second electrode region contact electrically.

The metal electrode layer may either be an anode or a cathode. Generally, the metal electrode layer is formed as a cathode.

### (1) First Electrode Region and Second Electrode Region

As long as the reflection characteristics of the first electrode region and the second electrode region are different with each other, for example, they may have different reflectances or different colors of the reflected lights.

In the case the reflectances of the first electrode region and the second electrode region are different with each other, it is preferable that the reflectance of the first electrode region is lower than the reflectance of the second electrode region.

The difference in the reflectances of the first electrode region and the second electrode region is preferably 10% or more, it is more preferably 15% or more, and it is further preferably 20% or more. With the difference in the reflectances provided in the range, a pattern shape formed with the first electrode region and the second electrode region at the time of non-light emission can be visually observed preferably.

The reflectance of the first electrode region may be lower than the reflectance of the second electrode region while satisfying the reflectance difference. Specifically, it is preferably 90% or less, it is more preferably 85% or less, and it is further preferably 80% or less. With the reflectance of the first electrode region provided in the range, a pattern shape formed with the first electrode region and the second electrode region at the time of non-light emission can be visually observed preferably. Moreover, with the reflectance of the first electrode region provided in the range, external light reflection can be restrained so as to improve the contrast in the first electrode region at the time of light emission. The lower limit value of the reflectance of the first electrode region is not particularly limited, but it is in general 40%.

The reflectance of the second electrode region may be higher than the reflectance of the first electrode region while satisfying the reflectance difference. Specifically, it is preferably 80% or more, it is more preferably 85% or more, and it is further preferably 90% or more. With the reflectance of the second electrode region provided in the range, a pattern shape formed with the first electrode region and the second electrode region at the time of non-light emission can be visually observed preferably. The upper limit value of the reflectance of the second electrode region is not particularly limited, but it is in general 100%.

The “reflectance” is obtained by measuring the reflectance of an irradiated light using the standard illuminant D65 (It is a daylight with the color temperature close to 6504K. It is a light having a spectral distribution of an average daylight. It includes a relatively large amount of the ultraviolet region.) as the light source. It refers to the reflectance of the entire measurement wavelength. The reflectance is measured with a spectrophotometer CM-2600d®, manufactured by Konica Minolta Holdings, Inc. The measurement conditions include the measurement diameter: φ8 mm, the observation field of view: 2°, and the UV: 100%.

Moreover, in the case the colors of the reflected lights in the first electrode region and the second electrode region are different, since the metal electrode layer has a metallic luster, the colors of the metallic luster in the first electrode region and the second electrode region may be different with each other, and furthermore, either the first electrode region or the second electrode region may be formed as a colorless transparent region for transmitting the light beam. In the case the colors of the metallic luster of the first electrode region and the second electrode region are provided differently, for example, gold (Au), aluminum (Al) and copper (Cu) show different colors of metallic luster. In the case either of the first electrode region or the second electrode region is provided as a colorless transparent region for transmitting the light beam, for example, indium zinc oxide (IZO) is used as a colorless transparent material.

The color of the reflected light can be measured with a spectrophotometer CM-2600d®, manufactured by Konica Minolta Holdings, Inc.

The first electrode region is a region with the first metal film disposed to face the organic EL layer side.

The expression “with the first metal film disposed to face the organic EL layer side” refers to a state with the first metal film out of the first metal film and the second metal film constituting the metal electrode layer is disposed to face the organic EL layer side. Specifically, it includes: the case the first metal film and the second metal film are formed successively on the organic EL layer with the first metal film disposed to face the organic EL layer side, and the case the first metal film is formed on the organic EL layer without formation of the second metal film and the first metal film is disposed to face the organic EL layer side.

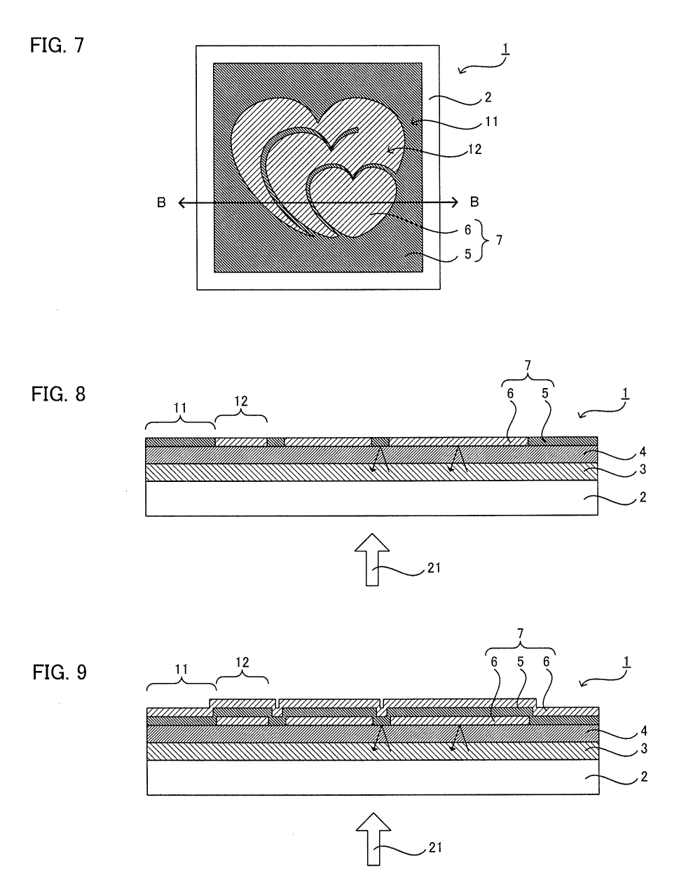

That is, in the first electrode region 11, as shown in FIG. 3, the first metal film 5 and the second metal film 6 may be laminated in this order on the organic EL layer 4, or the first metal film 5 may be formed on the organic EL layer 4 without formation of the second metal film as shown in FIGS. 7 and 8.

In particular, in the first electrode region, it is preferable that the first metal film and the second metal film are laminated in this order on the organic EL layer because it facilitates formation of the second metal film.

FIG. 7 is a top view of another example of an organic EL device of the present invention. FIG. 8 is a cross-sectional view taken on the line B-B of FIG. 7. Also in the case of the organic EL device shown in FIGS. 7 and 8, as in the case of the organic EL device shown in FIGS. 1 to 3, by providing the first electrode region and the second electrode region in a predetermined pattern shape, characters, graphics, and the like, can be observed visually at the time of non-light emission.

The second electrode region is a region with the second metal film disposed to face the organic EL layer side.

The expression “with the second metal film disposed to face the organic EL layer side” refers to a state with the second metal film out of the first metal film and the second metal film constituting the metal electrode layer is disposed to face the organic EL layer side. Specifically, it includes: the case the second metal film is formed on the organic EL layer without formation of the first metal film and the second metal film is disposed to face the organic EL layer side, the case the second metal film, the first metal film, and the second metal film are laminated successively on the organic EL layer with the second metal film disposed to face the organic EL layer side, and the case the second metal film and the first metal film are laminated successively on the organic EL layer and the second metal film is disposed to face the organic EL layer side.

That is, in the second electrode region 12, as shown in FIGS. 3 and 8, the second metal film 6 may be formed on the organic EL layer 4 without formation of the first metal film, as shown in FIG. 9, the second metal film 6; the second metal film 6, the first metal film 5, and the second metal film 6 may be laminated in this order on the organic EL layer 4; or although it is not shown in the drawings, the second metal film and the first metal film may be laminated in this order on the organic EL layer.

In the present invention, in general, the second metal film is formed on the organic EL layer without formation of the first metal film and the second metal film is disposed to face the organic EL layer side; or the second metal film, the first metal film, and the second metal film are laminated successively on the organic EL layer and the second metal film is disposed to face the organic EL layer side.

In the first electrode region and the second electrode region, the first metal film of the first electrode region and the second metal film of the second electrode region may contact electrically. As shown in FIGS. 1 to 3, the first electrode region 11 may be surrounded by the second electrode region 12; as shown in FIGS. 7 to 8, the second electrode region 12 may be surrounded by the first electrode region 11; or although it is not shown in the drawings, the first electrode region and the second electrode region may be disposed alternately.

### (2) First Metal Film and Second Metal Film

As the first metal film, any one satisfying the characteristics required for the first electrode region may be used, and as the second metal film, any one satisfying the characteristic required for the second electrode region may be used.

For example, in the case the reflectances of the first electrode region and the second electrode region are different with each other, it is preferable that the reflectance of the first electrode film is lower than the reflectance of the second metal film. The difference in the reflectances of the first electrode film and the second electrode film is preferably 10% or more, it is more preferably 15% or more, and it is further preferably 20% or more. With the difference of the reflectances provided in the range, a pattern shape formed with the first electrode region and the second electrode region at the time of non-light emission can be visually observed preferably.

The reflectance of the first electrode film may be lower than the reflectance of the second electrode film while satisfying the difference in reflectances. Specifically, it is preferably 90% or less, it is more preferably 85% or less, and it is further preferably 80% or less. With the reflectance of the first electrode film provided in the range, a pattern shape formed with the first electrode region and the second electrode region at the time of non-light emission can be visually observed preferably. Moreover, with the reflectance of the first electrode film provided in the range, external light reflection can be restrained so as to improve the contrast in the first electrode region at the time of light emission. The lower limit value of the reflectance of the first electrode film is not particularly limited, but it is in general 40%.

The reflectance of the second electrode film may be higher than the reflectance of the first electrode film while satisfying the reflectance difference. Specifically, it is preferably 80% or more, it is more preferably 85% or more, and it is further preferably 90% or more. With the reflectance of the second electrode film provided in the range, a pattern shape formed with the first electrode region and the second electrode region at the time of non-light emission can be visually observed preferably. The upper limit value of the reflectance of the second electrode film is not particularly limited, but it is in general 100%.

The method for measuring the reflectance is as mentioned above.

Moreover, for example, in the case the colors of the reflected lights in the first electrode region and the second electrode region are different with each other, it is preferable that the first metal film and the second metal film have different colors of reflected lights. That is, it is preferable that the first metal film and the second metal film provide different colors of metallic luster, or either the first metal film or the second metal film is colorless and transparent.

The method for measuring the color of the reflected light is as mentioned above.

The constituent materials for the first metal film and the second metal film may be selected optionally according to factors such as the characteristics required for the first metal film and the second metal film as mentioned above, and the arrangement of the first electrode region and the second electrode region. As mentioned above, since the metal electrode layer is formed in general as a cathode, it is preferable to use a metal material having a small work function as the constituent materials for the first metal film and the second metal film so as to facilitate electron injection.

As the constituent materials for the first metal film, a metal material having a small work function may be used. Examples thereof include: a mixture of a metal and its metal oxide such as a mixture of aluminum and aluminum oxide, a mixture of silver and silver oxide, and a mixture of magnesium and magnesium oxide; a single metal such as aluminum, silver, magnesium, gold, and copper; a magnesium alloy such as MgAg; an aluminum alloy such as AlLi, AlCa, and AlMg; alkaline metals and alkaline earth metals such as Li and Ca; and an alloy of alkaline metals and alkaline earth metals. For the first metal film, indium zinc oxide (IZO), indium tin oxide (ITO), and the like can also be used.

As the constituent materials for the second metal film, a metal material having a small work function may be used. Examples thereof include: a single metal such as aluminum, silver, magnesium, gold, and copper; a magnesium alloy such as MgAg; an aluminum alloy such as AlLi, AlCa, and AlMg; alkaline metals and alkaline earth metals such as Li and Ca; and an alloy of alkaline metals and alkaline earth metals. For the second metal film, indium zinc oxide (IZO), indium tin oxide (ITO), and the like can also be used.

In the case the reflectance of the first metal film is lower than the reflectance of the second metal film, the first metal film and the second metal film may contain the same metal element, or may contain different metal elements.

In particular, in the case the reflectance of the first metal film is lower than the reflectance of the second metal film, it is preferable that the first metal film and the second metal film contain the same metal element. In this case, by adjusting the amount of the oxygen included in the first metal film, the reflectance of the first metal film can be made lower than the reflectance of the second metal film.

In this case, by providing the first metal film as a mixture of a metal and its metal oxide such as a mixture of aluminum and aluminum oxide, a mixture of silver and silver oxide, and a mixture of magnesium and magnesium oxide, and providing the second metal film as a single metal such as aluminum, silver, and magnesium, the first metal film and the second metal film may contain the same metal element.

In the case the first metal film and the second metal film contain the same metal element, examples of the metal element include aluminum, silver, magnesium, and the like. In particular, aluminum is preferable because it has high reflectance.

Moreover, in the case the first metal film and the second metal film have different colors of reflected lights, it is preferable that the first metal film and the second metal film contain different metal elements. Thereby, the colors of the metallic luster of the first metal film and the second metal film can be different or either of the first metal film and the second metal film may be colorless and transparent.

The thickness of the first metal film is selected optionally according to the characteristics required to the first metal film as mentioned above, and the like.

In the case the reflectance of the first metal film is lower than the reflectance of the second metal film, the thickness of the first metal film is preferably 10 nm or less, it is more preferably 8 nm or less, and it is further preferably 5 nm or less. If the thickness of the first metal film is too thick, a desired reflectance may not be obtained. In consideration to the accuracy, the lower limit value of the thickness of the first metal film is in general about 1 nm.

Moreover, in the case the first metal film and the second metal film show different colors of reflected lights, the thickness of the first metal film may be of a common electrode thickness in an organic EL device. Specifically, it is about 20 nm to 500 nm.

The thickness of the second metal film is selected optionally according to factors such as the characteristics required to the second metal film as mentioned above.

In the case the reflectance of the first metal film is lower than the reflectance of the second metal film, the thickness of the second metal film is preferably 50 nm or more, it is more preferably 100 nm or more, and it is further preferably 200 nm or more. If the thickness of the second metal film is too thin, a desired reflectance may not be obtained. The upper limit value of the thickness of the second metal film may be of the upper value of a common electrode thickness in an organic EL device. It is, in general, about 500 nm.

Moreover, in the case the first metal film and the second metal film show different colors of reflected lights, the thickness of the second metal film may be of a common electrode thickness in an organic EL device. Specifically, it is about 20 nm to 500 nm.

As to the method for forming the first metal film and the second metal film, a method commonly used for forming an electrode may be used. Examples thereof include a common deposition process such as a vacuum deposition process, a sputtering process, and an ion plating process, and a method of applying a metal paste. As the method of applying a metal paste, a printing process, an ink jet process, and the like can be presented.

In particular, the vacuum deposition process and the method of applying a metal paste are preferable. Since the vacuum deposition process is a dry process and is a method with little damage to the organic EL layer so that it is suitable for lamination. Moreover, since the method of applying a metal paste is a wet process and the wet process is more suitable for application to a large area compared with the dry process. Even in the case of a wet process, a metal paste with a solvent, which does not influence on the organic EL layer, blended may be used. That is, by arranging the metal paste using the solvent resistance of the organic EL layer so as to avoid the influence on the organic EL layer, a wet process can also be used.

In particular, as shown in FIG. 3, in the case of forming the second metal film 6 on the entire surface of the substrate 2 with the first metal film 5 formed in a pattern, it is preferable to employ a vacuum deposition process. On the other hand, as shown in FIG. 8, in the case of forming the second metal film 6 in a region, where no first metal film 5 is formed, so as the first metal films and the second metal film 6 contact electrically, it is preferable to employ a method of applying a metal paste.

The method of forming the first metal film and the second metal film in the case the reflectance of the first metal film is lower than the reflectance of the second metal film will be mentioned later in the item of “13. Production method of the organic EL device”, and thus, an explanation is omitted here.

### (3) Other Constitutions

In the case of forming the first metal film or the second metal film by the sputtering process in the metal electrode layer used in the present invention, a charge transporting protection layer may be formed between the first metal film or the second metal film, and the organic EL layer. Since the charge transporting protection layer is formed, damage to the organic EL layer may be alleviated at the time of forming the first metal film or the second metal film by the sputtering process.

For example, in the case the charge transporting protection layer is formed between the organic EL layer and the first metal film at the time of forming the first metal film by the sputtering process, in the first electrode region, the charge transporting protection layer and the first metal film may be laminated on the organic EL layer, or the charge transporting protection layer, the first metal film, and the second metal film may be laminated on the organic EL layer. In this case, in the second electrode region, only the second metal film may be formed on the organic EL layer, or the second metal film, the charge transporting protection layer, the first metal film, and the second metal film may be laminated on the organic EL layer.

For example, in the case the charge transporting protection layer is formed between the organic EL layer and the second metal film at the time of forming the second metal film by the sputtering process, in the second electrode region, the charge transporting protection layer and the second metal film may be laminated on the organic EL layer, or the charge transporting protection layer, the second metal film, the first metal film, and the second metal film may be laminated on the organic EL layer. In this case, in the first electrode region, only the first metal film may be formed on the organic EL layer, or the first metal film, the charge transporting protection layer, and the second metal film may be laminated on the organic EL layer.

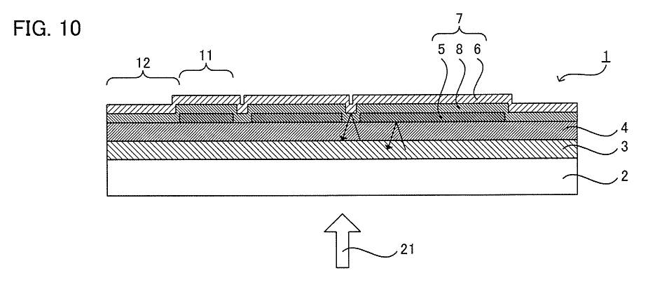

Specifically, in the case the charge transporting protection layer is formed between the organic EL layer and the second metal film at the time of forming the second metal film by the sputtering process, as shown in FIG. 10, the first metal film 5, the charge transporting protection layer 8, and the second metal film 6 may be laminated on the organic EL layer 4 in the first electrode region 11, and the charge transporting protection layer 8 and the second metal film 6 may be laminated on the organic EL layer 4 in the second electrode region 12.

Also in the case the charge transporting protection layer is formed, out of the first metal film and the second metal film constituting the metal electrode layer, a region with the first metal film disposed to face the organic EL layer side is the first electrode region, and a region with the second metal film disposed to face the organic EL layer side is the second electrode region.

The charge transporting protection layer is not particularly limited as long as the organic EL layer is protected from the damage at the time of forming the first metal film or the second metal film by the sputtering process and it has the charge transporting property. Examples thereof can include: triphenylamine derivatives such as N,N′-bis-(3-methyl phenyl)-N,N′-bis-(phenyl)-benzidine (TPD); quinoline derivatives such as tris(8-quinolinolato) aluminum complex (Alq₃); oxadiazol derivatives such as 2,5-bis(1-naphthyl)-1,3,4-oxadiazol (BND), and 2-(4-biphenyl)-5-(4-tert-butyl phenyl)-1,3,4-oxadiazol (PBD); triazol derivatives such as a 1,2,4-triazol derivative (TAZ); phenanthroline derivatives such as a triadine derivative and BCP; carbazol biphenyl derivatives such as 4,4′-di(9-carbazolyl) biphenyl (CBP); silol derivatives; perylene derivatives; pyridine derivatives; pyrimidine derivatives; quinoquisaline derivatives; cyclopentadiene derivatives; bisstylyl benzene derivatives; distylyl pyridine derivatives; diphenyl quinone derivatives; and nitro substituted fluorine derivatives.

The thickness of the charge transporting protection layer is preferably in a range of 10 nm to 1,000 nm, it is more preferably in a range of 50 nm to 500 nm, and it is further preferably in a range of 70 nm to 150 nm.

The method for forming the charge transporting protection layer is not particularly limited as long as it is a method with little damage to the organic EL layer. For example, a vacuum deposition process such as a resistance heat deposition process can be used.

### 2. Organic EL Layer

The organic EL layer used in the present invention is formed on a transparent electrode layer and includes a light emitting layer.

The organic EL layer has one layer or a plurality of layers of an organic layer including at least one light emitting layer. That is, the organic EL layer refers to a layer including at least a light emitting layer with the layer configuration with at least one organic layer. In general, in the case of forming the organic EL layer by a wet process of application, since lamination of a large number of layers is difficult due to use of a solvent so that one or two layers of the organic layer is used inmany cases. However, by skillfully preparing the organic material or by combining a vacuum deposition process, a larger number of layers may be formed.

As the layers including the organic EL layer other than the light emitting layer, layers such as a hole injecting layer, an electron injecting layer, a hole transporting layer, and en electron transporting layer can be presented. By providing the hole transporting function to the hole injecting layer, the hole transporting layer may be formed integrally with the hole injecting layer. Moreover, by providing the electron transporting function to the electron injecting layer, the electron transporting layer may be formed integrally with the electron injecting layer. Furthermore, as the layers including the organic EL layer, a layer for improving the re-coupling efficiency by preventing penetration of the hole or electron such as a carrier block layer and sputter protection layer can be presented.

Hereafter, each configuration in the organic EL layer will be explained.

### (1) Light Emitting Layer

As the material used for the light emitting layer in the present invention, light emitting materials such as a pigment based material, a metal complex based material, and a polymer based material can be presented.

Examples of the pigment based material can include: cyclopentadiene derivatives, tetraphenyl butadiene derivatives, triphenyl amine derivatives, oxadiazol derivatives, pyrazoloquinoline derivatives, distylyl benzene derivatives, distylyl arylene derivatives, sylol derivatives, a thiophene ring compound, a pyridine ring compound, perynone derivatives, perylene derivatives, oligothiophene derivatives, trifumanyl amine derivatives, oxadiazol dimers, and pyrazoline dimers.

Moreover, examples of the metal complex based material can include: metal complexes having a rare earth metal as the central metal such as Al, Zn, Be, Tb, Eu, or Dy, and as a ligand oxadiazol, thiadiazol, phenyl pyridine, phenyl benzoimidazol and a quinoline structure. For example, alumiquinolinol complexes, benzoquinolinol beryrium complexes, benzooxazol zinc complexes, benzthiazol zinc complexes, azomethyl zinc complexes, porphyline zinc complexes, and eurobium complexes can be presented.

Furthermore, examples of the polymer based material can include: a polyparaphenylene vinylene derivatives, polythiophene derivatives, polyparaphenylene derivatives, polysilane derivatives, polyacetylene derivatives, polyvinyl carbazol, polyfluorene derivatives, polyquinoquisaline derivatives, and copolymers thereof.

A doping agent may be added to the light emitting layer for the purpose of such as improvement of the light emitting efficiency, change of the light emitting wavelength. Examples of the doping agent can include: perylene derivatives, coumarin derivatives, ruburene derivatives, quinacrydone derivatives, squalium derivatives, porphyline derivatives, styryl based pigments, tetracene derivatives, pyrazoline derivatives, decacyclene, phenoxazone, quinoquisaline derivatives, carbazol derivatives, and fluorine derivatives.

The thickness of the light emitting layer is not particularly limited as long as it is a thickness capable of realizing the function of light emission by providing the field of re-coupling for the electron and the hole. For example, it may be about 1 nm to 500 nm.

It is preferable that the light emitting layer is formed in a pattern so as to have light emitting parts of a plurality of colors such as red, green, and blue. Thereby, an organic EL device enabling color display can be obtained.

As the method for forming the light emitting layer, for example, a vacuum deposition process, a printing process, an ink jet process, a spin coating process, a casting process, a dipping process, a bar coating process, a blade coating process, a roll coating process, a gravure coating process, a flexo printing process, a spray coating process, and a self-assembled process (an alternate adsorbing process, a self-assembled monolayer process) can be presented. In particular, the vacuum deposition process, the spin coating process, and the ink jet process are preferable.

### (2) Hole Injection Process

As mentioned above, by providing the hole transporting function to the hole injecting layer, the hole transporting layer may be formed integrally with the hole injecting layer. That is, the hole injecting layer may have only the hole injection function or may have both hole injection function and hole transporting function.

The material used for the hole injecting layer is not particularly limited as long as it is a material capable of stabilizing injection of the hole into the light emitting layer. In addition to the compounds presented for the light emitting materials for the light emitting layer, phenyl amine based; star burst type amine based; phthalocyanine based; oxides such as vanadium oxide, molybdenum oxide, ruthenium oxide, aluminum oxide, and titanium oxide; amorphous carbon; polyaniline; polythiophene; polyphenylene vinylene derivatives; and the like can be used. Specifically, bis(N-(1-naphtyl-N-phenyl)bendidine (α-NPD), 4,4,4-tris(3-methyl phenyl phenyl amino) triphenyl amine (MTDATA), poly 3,4 ethylene dioxythiophene-polystyrene sulfonic acid (PEDOT-PSS), polyvinyl carbazol (PVCz), and the like are presented.

Moreover, the thickness of the hole injecting layer is not particularly limited as long as it is a thickness capable of sufficiently realizing the hole injection function and the hole transporting function. Specifically, it is preferably in a range of 0.5 nm to 1,000 nm, and it is more preferably in a range of 10 nm to 500 nm.

Since the method for forming the hole injecting layer is same as the method for forming the light emitting layer, an explanation is omitted here.

### (3) Electron Injecting Layer

As mentioned above, by providing the electron transporting function to the electron injecting layer, the electron transporting layer may be formed integrally with the electron injecting layer. That is, the electron injecting layer may have only the electron injection function or it may have both electron injection function and electron transporting function.

The material used for the electron injecting layer is not particularly limited as long as it is a material capable of stabilizing injection of the electron into the light emitting layer. In addition to the compounds presented for the light emitting materials for the light emitting layer, alkaline metals, halides of alkaline metals, organic complexes of alkaline metals, such as aluminum-lithium alloys, lithium fluoride, strontium, magnesium oxide, magnesium fluoride, strontium fluoride, calcium fluoride, barium fluoride, aluminum oxide, strontium oxide, calcium, polymethyl methacrylate, polystyrene sodium sulfonate, lithium, cesium, and cesium fluoride can be used.

Moreover, a metal dope layer formed by doping an alkaline metal or an alkaline earth metal into an electron transporting organic material may be used as the electron injecting layer. As the electron transporting organic material, vasocuproin, vasophenanthroline, phenanthroline derivatives, and the like can be used. As the metal to be doped, Li, Cs, Ba, Sr, and the like can be presented.

The thickness of the electron injecting layer is not particularly limited as long as it is a thickness capable of sufficiently performing the electron injection function and the electron transporting function.

Since the method for forming the electron injecting layer is same as the method for forming the light emitting layer, an explanation is omitted here.

### (4) Electron Transporting Layer

The material used for the electron transporting layer is not particularly limited as long as it is a material capable of transporting the electron injected from the cathode into the light emitting layer. Examples thereof can include vasocuproin, vasophenanthroline, phenanthroline derivatives, triazol derivatives, oxadiazol derivatives, and derivatives of tris (8-quinolinolato) aluminum complex (Alq₃) .

The thickness of the electron transporting layer is not particularly limited as long as it is a thickness capable of sufficiently performing the electron transporting function.

Since the method for forming the electron transporting layer is same as the method for forming the light emitting layer, an explanation is omitted here.

### 3. Transparent Electrode Layer

The transparent electrode layer used in the present invention is formed on a substrate.

The transparent electrode layer is in general formed on the substrate in a stripe-like form.

Moreover, since the light is taken out from the transparent electrode layer side, the transparent electrode layer is transparent.

The transparent electrode layer may either be an anode or a cathode. However, it is in general formed as an anode.

As the anode, it is preferable to use a conductive material having a large work function so as to facilitate injection of the hole. Specifically, metals having a large work function such as ITO, indium oxide, and gold, conductive polymers such as polyaniline, polyacetylene, polyalkyl thiophene derivatives and polysilane derivatives, and the like can be presented.

The transparent electrode layer preferably has a small resistance. In general, a metal material is used therefor, however, an organic compound or an inorganic compound may be used as well.

As the method for forming the transparent electrode layer, general electrode film forming method can be used. Examples thereof can include the PVD process and the CVD process such as a vacuum deposition process, a sputtering process, and an ion plating process. Moreover, the transparent electrode layer patterning method is not particularly limited as long as it is a method capable of precisely forming a desired pattern. Specifically, a photolithography process, and the like can be presented.

### 4. Substrate

The substrate used in the present invention is not particularly limited as long as it supports the above-mentioned transparent electrode layer, organic EL layer, metal electrode layer, and the like with a predetermined strength. In the present invention, in the case the transparent electrode layer has a predetermined strength, the transparent electrode layer may also serve as the substrate. However, in general, the transparent electrode layer is formed on a substrate having a predetermined strength.

In the present invention, since the substrate side serves as the light taking out surface, the substrate is formed with a transparent material. As the method for forming such a substrate, a glass plate of soda lime glass, alkaline glass, lead alkaline glass, borosilicate glass, aluminosilicate glass, and silica glass; a resin substrate to be shaped in a film-like form; or the like can be used. The resin used for the resin substrate is preferably a polymer material having relatively high solvent resistance and heat resistance. Specifically, examples thereof include a fluorine based resin, polyethylene, polypropylene, polyvinyl chloride, polyvinyl fluoride, polystyrene, an ABS resin, polyamide, polyacetal, polyester, polycarbonate, modified polyphenylene ether, polysulfone, polyarylate, polyether imide, polyether sulfone, polyamide imide, polyimide, polyphenylene sulfide, liquid crystalline polyester, polyethylene terephthalate, polybutylene terephthalate, polyethylene naphthalate, polycyclohexylene dimethylene terephthalate, polyoxy methylene, polyether sulfoen, polyether ether ketone, polyacrylate, an acrylonitrile-styrene resin, a phenol resin, a urea resin, a melamine resin, an unsaturated polyester resin, an epoxy resin, polyurethane, a silicone resin, and amorphous polyolefin. Moreover, in addition to the above-mentioned, a polymer material satisfying predetermined conditions may be used, and a copolymer of two or more kinds may also be used. Furthermore as needed, a substrate having gas barrier properties for shielding moisture content and a gas such as oxygen may be used as well.

### 5. Insulating Layer

In the present invention, it is preferable that an insulating layer is formed on the substrate with the transparent electrode layer formed because short circuit derived from contact of the transparent electrode layer and the metal electrode layer can be prevented by the insulating layer. The insulating layer is formed preferably in a state covering the end part of the transparent electrode layer. Since the thickness of the organic EL layer is thinner at the end part of the transparent electrode layer, short circuit is hardly generated by forming the insulating layer. Moreover, electric connection of the adjacent light emitting regions can be prevented. The portion with the insulating layer formed may be a region not contributing to the light emission.

As the material for forming the insulating layer, photosetting resins such as photosensitive polyimide resins and acrylic resins, thermosetting resins, inorganic materials, and the like can be presented.

As the method for forming the insulating layer, a common method such as a photolithography process and a printing process can be used.

### 6. Partition Wall

In the present invention, a partition wall may be formed on the insulating layer like stripes so as to cross the stripe-like transparent electrode layer. According to the partition wall, the metal electrode layer can be cut into a stripe-like form.

Since the metal electrode layer can be cut with a predetermined height of the partition wall, the cross-sectional shape of the partition wall is not particularly limited. Examples thereof include a rectangular shape, a trapezoidal (forward tapered) shape, and an inverse tapered shape. Preferable examples include an overhung shape such as an inverse tapered shape.

The height of the partition wall is set such that the height from the substrate surface to the partition wall surface is higher than the height from the substrate surface to the metal electrode layer surface in the central part of the light emitting region.

Moreover, examples of the material for forming the partition wall can include photosetting resins such as a photosensitive polyimide resin, an acrylic resin, a novolak resin, a styrene resin, a phenol resin, and a melamine resin, thermosetting resins, and inorganic materials.

As the method for forming the partition wall, a common method such as a photolithography process and a printing process can be used.

### B. Production Method of Organic EL Device

Then, the production method of the organic EL device of the present invention will be explained. The production method of the organic EL device of the present invention can be classified into two aspects according to the formation order of the first metal film and the second metal film. Hereafter, each aspect will be explained independently.

### I. First Aspect

The first aspect of the production method of an organic EL device of the present invention comprises a metal electrode layer forming step which further comprises a first metal film forming step and a second metal film forming step, wherein the first metal film forming step is for forming a first metal film and includes: a first metal film forming layer forming step for forming a first metal film forming layer in a pattern in vacuum on a substrate with a transparent electrode layer and an organic EL layer including a light emitting layer laminated successively, and an exposing step of exposing the first metal film forming layer to atmosphere including oxygen; the second metal film forming step is for forming a second metal film in vacuum onto the entire surface of the substrate with the first metal film formed in the pattern; and the metal electrode layer forming step is for forming a metal electrode layer which comprises: a first electrode region with the first metal film disposed to face the organic EL layer side, and a second electrode region with the second metal film disposed to face the organic EL layer side.

The production method of an organic EL device of the present invention will be explained with reference to the drawings.

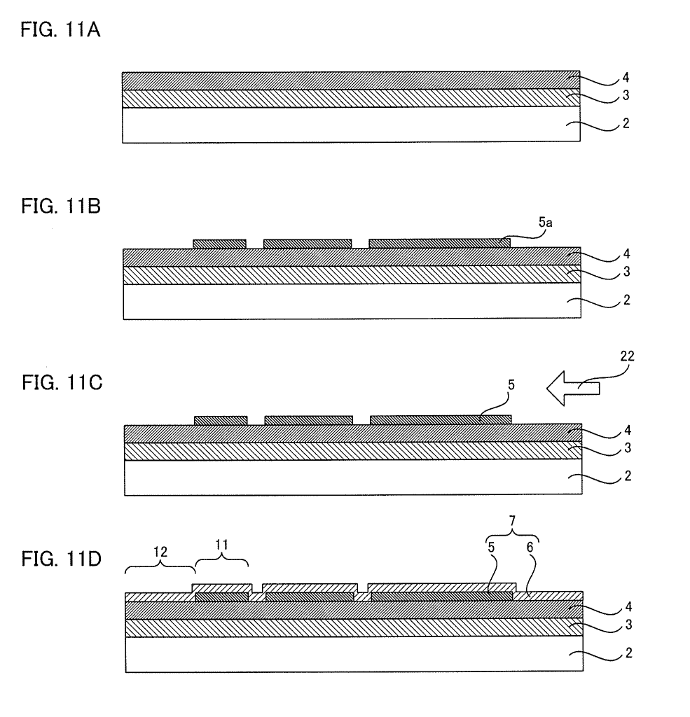

FIGS. 11A to 11D is a step diagram showing an example of a production method of an organic EL device of the present invention. First, a transparent electrode layer 3 is formed on a substrate 2 and an organic El layer 4 is formed on the transparent electrode layer 3 (FIG. 11A). Then, a first metal film forming layer 5a is formed in a pattern in vacuum on the substrate 2 with the organic EL layer 4 formed (FIG. 11B, first metal film forming layer forming step). Then, in an atmospheric pressure state, the first metal film forming layer 5a is exposed to atmosphere 22 including oxygen (FIG. 11C, exposing step) for forming a first metal film 5 (FIGS. 11B to 11C, first metal film forming step). At the time, it is presumed that the surface of the first metal film forming layer 5a is oxidized by exposing the first metal film forming layer 5a to atmosphere including oxygen. Therefore, the first metal film 5 obtained by exposure of the first metal film forming layer 5a to the atmosphere 22 including oxygen has the surface oxidized so that it is presumed that a metal oxide film is formed on the surface.

Then, a second metal film 6 is formed in vacuum on the entire surface of the substrate with the first metal film 5 formed in a pattern (FIG. 11D, second metal film forming step). Thereby, a metal electrode layer 7 including: a first electrode region 11 with the first metal film 5 disposed to face the organic EL layer 4 side, and a second electrode region 12 with the second metal film 6 disposed to face the organic El layer 4 side is formed (FIGS. 11B to 11D, metal electrode layer forming step).

As mentioned above, it is presumed that the first metal film has the surface oxidized and a metal oxide film is formed on the surface. On the other hand, since the second metal film is formed in vacuum, it is presumed that its surface is not oxidized. If a metal is oxidized, its reflection characteristics are changed. In general, in the case a metal is oxidized, its metal luster is lost. As a result, its reflectance is lowered. Therefore, the first electrode region 11 with the first metal film 5 disposed to face the organic EL layer 4 side and the second electrode region 12 with the second metal film 6 disposed to face the organic EL layer 4 side have different reflection characteristics. Specifically, the reflectance of the first electrode region 11 with the first metal film 5 disposed to face the organic EL layer 4 side is lower than the reflectance of the second electrode region 12 with the second metal film 6 disposed to face the organic EL layer 4 side.

Therefore, in the present invention, as described in the item of “A. Organic EL device” mentioned above, a pattern shape formed by the first electrode region and the second electrode region can be observed visually at the time of non-light emission so that an organic EL device enabling visual observation of characters, graphics, and the like can be obtained. Moreover, an organic EL device capable of displaying by light emission a pattern shape different from the pattern shape formed by the first electrode region and the second electrode region at the time of light emission can be obtained. That is, an organic EL device capable of displaying by light emission a desired pattern at the time of light emission and enabling visual observation of a predetermined pattern at the time of non-light emission with a preferable appearance at the time of non-light emission can be produced.

Here, it is presumed that the conductivity of a metal is changed according to oxidation thereof. Since the first metal film constitutes the metal electrode layer, conductivity decline derived from oxidation is concerned. However, by controlling factors such as the thickness of the first metal film forming layer and the degree of the oxidation, it is possible to change the reflectance without changing the conductivity.

Hereafter, each step in the production method of an organic EL device of the present invention will be explained.

### 1. Metal Electrode Layer Forming Step

The metal electrode layer forming step in the present invention comprises a first metal film forming step and a second metal film forming step, wherein the first metal film forming step is for forming a first metal film and includes: a first metal film forming layer forming step for forming a first metal film forming layer in a pattern in vacuum on a substrate with a transparent electrode layer and an organic EL layer including a light emitting layer laminated successively, and an exposing step of exposing the first metal film forming layer to the atmosphere including oxygen; the second metal film forming step is for forming a second metal film in vacuum onto the substrate with the first metal film formed in a pattern; and a metal electrode layer forming step is for forming a metal electrode layer which comprises: a first electrode region with the first metal film disposed to face the organic EL layer side, and a second electrode region with the second metal film disposed to face the organic EL layer side.

Hereafter, each step of the metal electrode layer forming step will be explained.

### (1) First Metal Film Forming Step

The first metal film forming step of the present invention is for forming a first metal film and comprises: a first metal film forming layer forming step for forming a first metal film forming layer in a pattern in vacuum on a substrate with a transparent electrode layer and an organic EL layer including a light emitting layer laminated successively, and an exposing step of exposing the first metal film forming layer to the atmosphere including oxygen.

Hereafter, each step in the first metal film forming step will be explained.

### (i). First Metal Film Forming Layer Forming Step

The first metal film forming layer forming step in the present invention is a step of forming a first metal film forming layer in a pattern in vacuum on a substrate with a transparent electrode layer and an organic EL layer including a light emitting layer laminated successively.

Since the substrate, the transparent electrode layer and the organic EL layer are described in the item of “A. Organic EL device”, an explanation is omitted here.

The materials used for formation of the first metal film forming layer may be a metal material having a small work function as described in the item of “A. Organic EL device”. In particular, in the present invention, since the first metal film forming layer is exposed in the atmosphere including oxygen for changing its reflection characteristics in the exposing step, specifically, it is presumed that the surface of the first metal film forming layer is oxidized in the exposing step, it is preferable to use a metal easily enabling formation of an oxide film. As such a metal, aluminum, silver, magnesium, and the like are presented. In particular, aluminum is preferable because aluminum shows a high reflectance.

The method for forming the first metal film forming layer is not particularly limited as long as it is a method capable of forming the first metal film forming layer in a pattern in vacuum so that a common electrode forming method can be used. For example, a mask deposition process using a mask, such as a vacuum deposition process, a sputtering process, and an ion plating process are presented.

In particular, the vacuum deposition process using a mask is preferable. Since the vacuum deposition process is a dry process and poses little damage to the organic EL layer, it is suitable for lamination.

At the time of forming the first metal film forming layer in a pattern in vacuum, the pressure may be a common pressure at the time of forming an electrode. Specifically, it is preferably 1×10⁻⁵ torr or less, it is more preferably 1×10⁻⁶ torr or less, and it is further preferably 1×10⁻⁷ torr or less.

The thickness of the first metal film forming layer is preferably in a range of 1 nm to 50 nm, it is more preferably in a range of 1 nm to 20 nm, and it is further preferably in a range of 1 nm to 5 nm. If the thickness of the first metal film forming layer is too thin, formation of an even film may be difficult. Moreover, since it is presumed that oxidation of the first metal film forming layer in the exposing step to be described later is only in the vicinity of the surface, if the thickness of the first metal film forming layer is too thick, a desired reflectance may not be obtained after the exposing step.

### (ii) Exposing Step

The exposing step in the present invention is a step of exposing the metal film forming layer to the atmosphere including oxygen.

In this step, the atmosphere may be atmosphere including oxygen. The atmosphere including oxygen may have a 1% or less oxygen amount.

Moreover, at the time of exposing the first metal film forming layer to the atmosphere including oxygen, the pressure may be about atmospheric pressure, and with presence of oxygen, it may be a low vacuum (1×10⁻³ torr or more).

The time of exposing the first metal film forming layer to the atmosphere including oxygen is adjusted optionally according to factors such as a purposed reflectance, the kind of the metals contained in the first metal film forming layer, and the thickness of the first metal film forming layer. Specifically, the time is preferably in a range of 1 minute to 30 minutes, it is more preferably in a range of 1 minute to 10 minutes, and it is further preferably in a range of 1 minute to 5 minutes. If the time is too short, the surface of the first metal film forming layer cannot be oxidized sufficiently so that a desired reflectance may not be obtained.

(iii) Others

In the present invention, the first metal film may be formed with a plurality of layers laminated by repeatedly carrying out the first metal film forming layer forming step and exposing step.

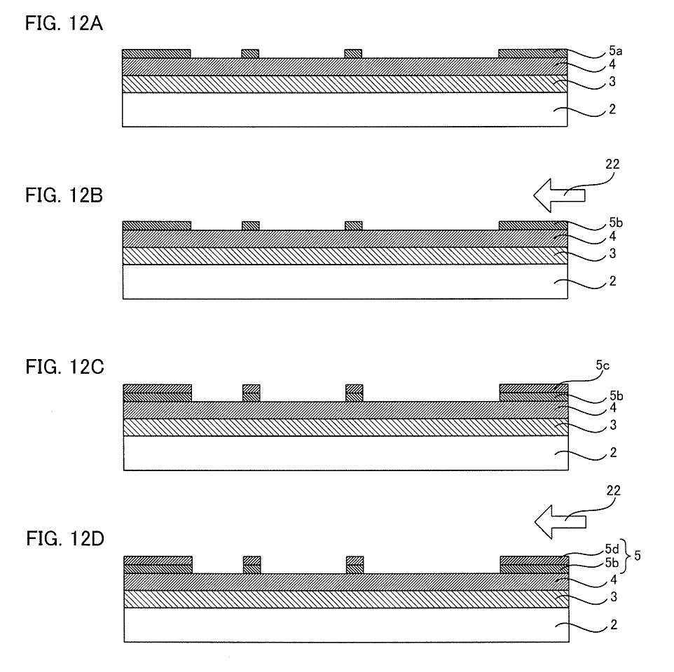

In the example shown in FIGS. 12A to 12D, first, by forming a first metal film forming layer 5a of the first layer in a pattern in vacuum on a substrate 2 with an organic EL layer 4 formed (FIG. 12A, first metal film forming layer forming step), and exposing the first metal film forming layer 5a to the atmosphere 22 including oxygen (FIG. 12B, exposing step), a metal film 5b of the first layer is formed. Then, by forming a first metal film forming layer 5c of the second layer in a pattern in vacuum on the substrate 2 with the metal film 5b of the first layer formed (FIG. 12C, first metal film forming layer forming step), and exposing the first metal film forming layer 5C to the atmosphere 22 including oxygen (FIG. 12D, exposing step), a metal film 5d of the second layer is formed. Thereby, a first metal film 5 with the metal films 5b, 5d of the two layers laminated is obtained. That is, in the example shown in FIGS. 12A to 12D, the first metal film forming layer forming step and the exposing step are repeated for two times.

As mentioned above, since it is presumed that only the vicinity of the surface of the first metal film forming layer is oxidized in the exposing step, if the thickness of the first metal film forming layer is too thick, a desired reflectance may not be obtained after the exposing step. On the other hand, if the thickness of the first metal film is too thin, a desired conductivity may not be obtained. Therefore, by repeatedly carrying out the first metal film forming layer forming step and the exposing step, the first metal film having a desired reflectance can be obtained.

In the case of forming the first metal film with a plurality of layers laminated, the number of laminations is not particularly limited as long as a first metal film having a desired reflectance is obtained. In general, it is about 2 layers to 5 layers, it is preferably in a range of 2 layers to 4 layers, and it is further preferably in a range of 2 layers to 3 layers.

That is, in the case of repeatedly carrying out the first metal film forming layer forming step and the exposing step, the number of the repetition is not particularly limited as long as the first metal film having a desired reflectance is obtained. In general, it is about once to four times, it is preferably in a range of once to three times, and it is further preferably in a range of once to twice. If the number is too large, the production process is complicated.

Since the other points of the first metal film are described in the item of “A. Organic EL device”, an explanation is omitted here.

### (2) Second Metal Film Forming Step

The second metal film forming step in the present invention is a step of forming a second metal film in vacuum on the entire surface of the substrate with the first metal film formed in a pattern.

The materials used for formation of the second metal film may be a metal material having a small work function as described in the item of “A. Organic EL device”. In particular, it is preferable to form a film of the same metal in the first metal film forming step and the second metal film forming step. That is, it is preferable that the materials used for formation of the second metal film are same as the materials used for formation of the first metal film forming layer. By controlling the degree of oxidation of the first metal film in the exposing step, the reflectance of the first metal film can be adjusted so that the first metal film and the second metal film can be formed with different reflectances.

Specifically, as the materials used for formation of the second metal film, aluminum, silver, magnesium, and the like are preferable, and aluminum is more preferable.

The method for forming the second metal film is not particularly limited as long as it is a method capable of forming the second metal film in vacuum. As the method for forming the second metal film, a common electrode forming method can be used. For example, a deposition process, such as a vacuum deposition process, a sputtering process, and an ion plating process can be presented. In particular, the vacuum deposition process is preferable. Since the vacuum deposition process is a dry process and poses little damage to the organic EL layer, it is suitable for lamination.

At the time of forming the second metal film in a pattern in vacuum, the pressure may be a common pressure at the time of forming an electrode. Specifically, it is preferably 1×10⁻⁵ torr or less, it is more preferably 1×10⁻⁶ torr or less, and it is further preferably 1×10⁻⁷ torr or less.

Since the other points of the second metal film are described in the item of “A. Organic EL device”, an explanation is omitted here.

### (3) Others

In the metal electrode layer forming step in the present invention, by carrying out the first metal film forming step and the second metal film forming step mentioned above, the metal electrode layer including the first electrode region with the first metal film disposed to face the organic EL layer side and the second electrode region with the second metal film disposed to face the organic EL layer side is formed.

Since the first electrode region and the second electrode region are described in the item of “A. Organic EL device”, an explanation is omitted here.

### 2. Other Steps

The production method of an organic EL device of the present invention may include other steps such as a step of forming an insulating layer on a substrate with a transparent electrode layer formed, a step of forming a partition wall on an insulating layer, and a step of forming an organic EL layer on a substrate with a transparent electrode layer formed.

Since the insulating layer and its forming method, the partition wall and its forming method, the organic EL layer and its forming method, and the like are described in the item of “A. Organic EL device”, an explanation is omitted here.

### II. Second Aspect

The second aspect of the production method of an organic EL device of the present invention comprises a metal electrode layer forming step which further comprises a first-second metal film forming step, a first metal film forming step, and a second-first metal film forming step, wherein the first-second metal film forming step is for forming a second metal film in a pattern in vacuum on a substrate with a transparent electrode layer and an organic EL layer including a light emitting layer laminated successively; the first metal film forming step is for forming a first metal film and includes a first metal film forming layer forming step of forming a first metal film forming layer in vacuum on the entire surface of the substrate with the second metal film formed, and an exposing step of exposing the first metal film forming layer to atmosphere including oxygen; the second-second metal film forming step is for forming a second metal film in vacuum on the entire surface of the substrate with the second metal film and the first metal film formed; and the metal electrode layer forming step is for forming a metal electrode layer which comprises: a first electrode region with the first metal film disposed to face the organic EL layer side, and a second electrode region with the second metal film disposed to face the organic EL layer side.

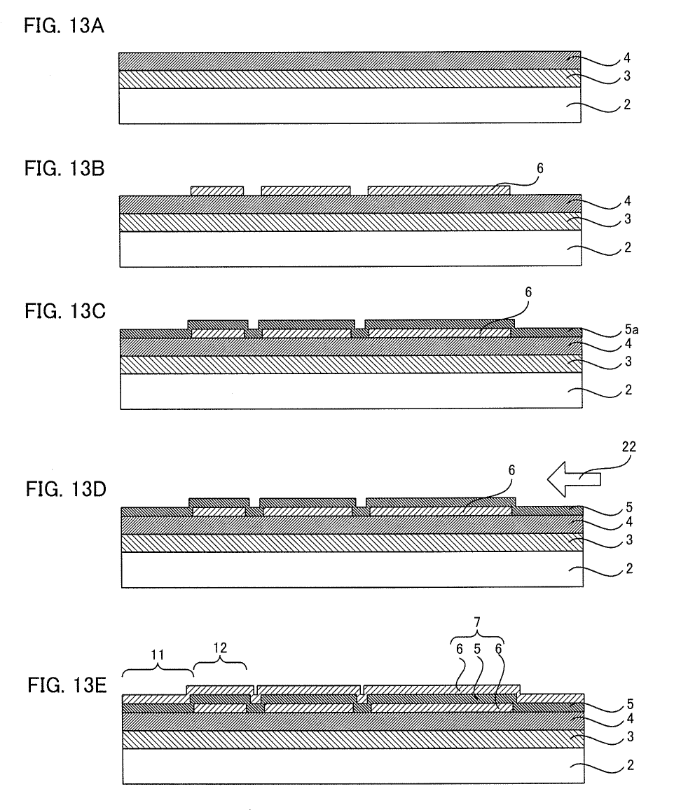

FIGS. 13A to 13E is a step diagram showing an example of a production method of an organic EL device of the present invention. First, a transparent electrode layer 3 is formed on a substrate 2 and an organic EL layer 4 is formed on a transparent electrode layer 3 (FIG. 13A). Then, a second metal 6 is formed in a pattern in vacuum on the substrate 2 with the organic EL layer 4 formed (FIG. 13B, first-second metal film forming step).

Then, a first metal film forming layer 5a is formed in vacuum on the entire surface of the substrate with the second metal film 6 formed (FIG. 13C, first metal film forming layer forming step). Then, in an atmospheric pressure state, the first metal film forming layer 5a is exposed to atmosphere 22 including oxygen (FIG. 13D, exposing step) for forming a first metal film 5 (FIGS. 13C to 13D, first metal film forming step). At the time, it is presumed that the surface of the first metal film forming layer 5a is oxidized by exposing the first metal film forming layer 5a to the atmosphere including oxygen. Therefore, the first metal film 5 obtained by exposure of the first metal film forming layer 5a to the atmosphere 22 including oxygen has the surface oxidized so that it is presumed that a metal oxide film is formed on the surface.

Then, a second metal film 6 is formed in vacuum on the entire surface of the substrate with the second metal film 6 and the first metal film 5 formed (FIG. 13E, second-second metal film forming step). Thereby, a metal electrode layer 7 including a first electrode region 11 with the first metal film 5 disposed to face the organic EL layer 4 side and a second electrode region 12 with the second metal film 6 disposed to face the organic El layer 4 side is formed (FIGS. 13B to 13D, metal electrode layer forming step).

As mentioned above, it is presumed that the first metal film has the surface oxidized with a metal oxide film formed on the surface. On the other hand, since the second metal film is formed in vacuum, it is presumed that its surface is not oxidized. If a metal is oxidized, its reflection characteristics are changed. In general, in the case a metal is oxidized, its metal luster is lost. As a result, its reflectance is lowered. Therefore, the first electrode region 11 with the first metal film 5 disposed to face the organic EL layer 4 side and the second electrode region 12 with the second metal film 6 disposed to face the organic EL layer 4 side have different reflection characteristics. Specifically, the reflectance of the first electrode region 11 with the first metal film 5 disposed to face the organic EL layer 4 side is lower than the reflectance of the second electrode region 12 with the second metal film 6 disposed to face the organic EL layer 4 side.

Therefore, in the present invention, as described in the item of “A. Organic EL device”, a pattern shape formed by the first electrode region and the second electrode region can be observed visually at the time of non-light emission so that an organic EL device enabling visual observation of characters, graphics, and the like can be obtained. Moreover, an organic EL device capable of displaying by light emission a pattern shape different from the pattern shape formed by the first electrode region and the second electrode region at the time of light emission can be obtained. That is, an organic EL device capable of displaying by light emission a desired pattern at the time of light emission and enabling visual observation of a predetermined pattern at the time of non-light emission with a preferable appearance at the time of non-light emission can be produced.

Here, it is presumed that the conductivity of a metal is changed according to oxidation thereof. Since the first metal film constitutes the metal electrode layer, conductivity decline derived from oxidation is concerned. However, by controlling factors such as the thickness of the first metal film forming layer and the degree of the oxidation, it is possible to change the reflectance without changing the conductivity.

Since the second-second metal film forming step is same as the second metal film forming step of the first aspect, an explanation is omitted here. Hereafter, the other steps in the production method of an organic EL device of this aspect will be explained.

### 1. First-Second Metal Film Forming Step

The first-second metal film forming step in this aspect is a step of forming a second metal film in a pattern in vacuum on a substrate with a transparent electrode layer and an organic EL layer including a light emitting layer laminated successively.

The method for forming the second metal film is not particularly limited as long as it is a method capable of forming the second metal film in a pattern in vacuum so that a common electrode forming method can be used. For example, a mask deposition process using a mask, such as a vacuum deposition process, a sputtering process, and an ion plating process can be presented.

In particular, the vacuum deposition process using a mask is preferable. Since the vacuum deposition process is a dry process and poses little damage to the organic EL layer, it is suitable for lamination.

Since the other points are same as the second metal film forming step of the first aspect, an explanation is omitted here.

### 2. First Metal Film Forming Step

The first metal film forming step in this aspect is a step of forming a first metal film and includes: a first metal film forming layer forming step of forming a first metal film forming layer in vacuum on the entire surface of a substrate with the second metal film formed, and an exposing step of exposing the first metal film forming layer to the atmosphere including oxygen.

The method for forming the first metal film forming layer is not particularly limited as long as it is a method capable of forming the first metal film forming layer in vacuum. As the method for forming the first metal film forming layer, a common electrode forming method can be used. For example, a deposition process, such as a vacuum deposition process, a sputtering process, and an ion plating process can be presented. In particular, the vacuum deposition process is preferable. Since the vacuum deposition process is a dry process and poses little damage to the organic EL layer, it is suitable for lamination.

Since the other points are same as the first metal film forming step of the first aspect, an explanation is omitted here.

The present invention is not limited to the above-mentioned embodiments. The embodiments are merely examples so that any one having substantially the same configuration as the technological idea mentioned in the scope of the claims of the present invention with the same effects is incorporated in the technological scope of the present invention.

### EXAMPLES

Hereafter, the present invention will be explained specifically with reference to examples and a comparative example.

### Example 1

### Formation of Transparent Electrode Layer

First, an indium tin oxide (ITO) electrode film of a 200 nm film thickness was formed on a glass substrate (thickness: 0.7 mm) by an ion plating process. By applying a photosensitive resist on the ITO electrode film followed by mask exposure, development, and etching of the ITO electrode film, 30 pieces of a stripe-like transparent electrode layer were formed by a 1.7 mm width and by a 2.3 mm pitch.

### (Formation of Insulating Layer)

Then, by applying a washing process and a ultraviolet ray plasma washing to the glass substrate (thickness: 0.7 mm), applying a positive type photosensitive resist containing as the main component a polyimide precursor by a spin coating process, and patterning by a photolithography process, an insulating layer (thickness: 1.5 μm) was formed on the transparent electrode layer so that a 1.5 mm×1.5 mm light emitting area (opening part) was present by a 2.3 mm pitch.

### (Formation of Partition Wall)

Then, by applying a washing process and a ultraviolet ray plasma washing to the glass substrate with the insulating layer formed, applying a negative type photosensitive resist made of a novolak resin, a phenol resin, and a melamine resin by a spin coating process, and patterning by a photolithography process, a stripe-like partition wall with an inverse tapered cross-sectional shape was formed in parallel on the insulating layer so as to be orthogonal with the transparent electrode layer. At the time, the number of small partition walls constituting the partition wall was 2 pieces (2 lines). Moreover, the partition wall was formedwith the interval of the small partition walls of 30 μm. The small partition wall has a 50 μm width, a 4 μm thickness, and an inverse tapered angle of 50°.

### (Preparation of Ink for Hole Injecting Layer and Ink for Red Light Emitting Layer)

Then, an ink A1 for a hole injecting layer of the following composition was prepared. The viscosity (ink temperature: 23° C.) of the ink A1 at a 100/second shear speed measured with a visco-elasticity meter MCR 301 Type® manufactured by Physica Corp. by a steady flow measurement mode was 15 cP. Moreover, the dynamic surface tension (ink temperature: 23° C.) at 2 Hz measured with SITAt 60/2 (manufactured by SITAM esstechnik GmbH) was 30 dyne/cm.

<Composition of Ink A1 for Hole Injecting layer>

| | |
|---|---|
| PEDOT (poly(3,4)ethylene dioxythiophene)/PSS | 70% by weight |
| (polystyrene sulfonate) (mixing ratio = 1/20) | |
| (Baytron PCH8000 ®, manufactured by Bayer AG) | |
| Solvent mixture (water:isopropyl alcohol (boiling | 30% by weight |
| point: 82.4° C.) = 70:30) | |

Then, an ink B1 for a red light emitting layer of the following composition was prepared. The viscosity (ink temperature: 23° C.) of the ink B1 at a 100/second shear speed measured in the same manner as in the ink A1 was 80 cP. Moreover, the surface tension of mesitylene and tetralin used as the solvent was measured at 20° C. with surface tension meter CBVP-Z type® manufactured by Kyowa Interface Science Co., Ltd.

### <Composition of Ink B1 for Red Light Emitting Layer>

| | |
|---|---|
| •Polyfluorene derivative based | 2.5% by weight |
| red light emitting material | |
| (molecular weight: 300,000) | |
| •Solvent (solvent mixture | 97.5% by weight |
| of mesitylene:tetralin = 50:50) | |

(surface tension of the solvent mixture = 32 dyne/cm, boiling point = 186° C.)
(surface tension of mesitylene = 28 dyne/cm, boiling point = 165° C.)
(surface tension of tetralin = 35.5 dyne/cm, boiling point = 207° C.)

### (Formation of Hole Injecting Layer and Light Emitting Layer)

As the gravure plate, a plate-like gravure block (effective width 80 mm) including a square cell (one side of the cell: 100 μm, depth of the cell: 35 μm) arranged in a lattice shape so as to have a 25 μm cell interval was prepared. According to the gravure bplate, the diagonal line direction of the square cell coincides with the operation direction of the blanket to be described later.

Then, as the resin film, an easy bonding polyethylene terephthalate (PET) film (U10®, manufacturedby Toray Industries, Inc., thickness: 100 μm, surface tension: 60 dyne/cm) was prepared. The film surface tension was obtained by measuring the contact angle θ with an automatic contact angle meter (Drop Master 700 Type®, manufactured by Kyowa Interface Science Co., Ltd.,), using two or more kinds of liquid with their surface tensions known (reference substance) and calculating based on equation: γs (surface tension of resin film)=γL (surface tension of liquid) cos θ+γSL (surface tension of resin film and liquid).

Then, a blanket was produced by attaching the resin film on the circumferential surface of a blanket trunk having a 12 cm diameter and a 30 cm trunk width (including a cushion layer (hardness: 70°) on the surface). The hardness of the cushion layer is the Type A hardness according to the JIS (K6253) durometer hardness test.

Then, with the gravure plate and blanket mounted on a flat base offset printing machine, the inside of the cell was filled with the ink by supplying the ink A1 for the hole injection to the gravure plate and removing the unnecessary ink with a blade. Then, by receiving the ink from the gravure plate to the blanket, and transferring the ink from the blanket onto the glass substrate with the partition wall, and the like formed, a hole injecting layer (thickness: about 70 nm) was formed. The printing speed was 1,000 mm/second, and the drying operation was carried out on a hot plate set at 120° C. for 1 hour. The hole injecting layer was formed by 80 mm×80 mm so as to cover the opening part of the insulating layer.

Then, by supplying the ink B1 for the red light emitting layer to the gravure plate, by the same working process as in the case of the formation of the hole injecting layer, a red light emitting layer (thickness: about 70 nm) was formed. The printing speed was 1,000 mm/second, and the drying operation was carried out on a hot plate set at 180° C. for 1 hour. The red light emitting layer was formed by 80 mm×80 mm so as to cover the hole injecting layer.

### (Formation of Electron Injecting Layer)

A metal mask having an opening part of a 90 mm×90 mm size on the surface side with the red light emitting layer formed was disposed to face the light emitting area (opening part) of the insulating layer. Then, an electron injecting layer (thickness: 10 nm) was formed by depositing calcium (deposition rate=0.1 nm/second) through a vacuum deposition process via the mask.

### (Formation of Metal Electrode Layer)

Then, by depositing aluminum (deposition rate=0.4 nm/second) by a vacuum deposition process with a heart shaped-metal mask, an aluminum film (thickness: 5 nm) having a heart shaped-opening part was formed on the electron injecting layer. Then, the aluminum film was exposed to an oxygen amount 0.2 ppm environment under an atmospheric pressure for 5 minutes. Thereby, a first metal film was obtained.

Then, with the metal mask used for the formation of the electron injecting layer used as it is, aluminum was deposited (deposition rate=0.4 nm/second) by a vacuum deposition process. Thereby, a second metal film (thickness: 300 nm) made of aluminum of a 90 mm×90 mm size was formed on the electron injecting layer with the first metal film formed.

Finally, by attaching a sealing plate via a ultraviolet ray curing type adhesive on the surface side with the second metal film formed, an organic EL device was obtained.

The reflectance of the organic EL device of the example 1 was measured. It was 88% in a region with the first metal film facing the organic EL layer side, and it was 96% in a region with the second metal film facing the organic EL layer side. Therefore, a heart shaped-pattern was observed in the organic EL device of the example 1. Moreover, this device was capable of character display by the passive drive.

### Comparative Example 1

An organic EL device was produced in the same manner as in the example 1 except that the aluminum film having a heart shaped-opening part was not exposed to atmosphere including oxygen in the formation of the metal electrode layer.

The reflectance of the organic EL device of the comparative example 1 was measured. It was 96% in a region with the first metal film facing the organic EL layer side, and it was also 96% in a region with the second metal film facing the organic EL layer side. Therefore, a heart shaped-pattern was not observed in the organic EL device of the comparative example 1. This device was capable of character display by the passive drive.

### Example 2

An organic EL device was produced in the same manner as in the example 1 except that the first metal film was formed as follows.

### (Formation of Metal Electrode Layer)

By depositing aluminum (deposition rate=0.4 nm/second) by a vacuum deposition process with a heart shaped-metal mask, an aluminum film (thickness: 5 nm) having a heart shaped-opening part was formed on the electron injecting layer. Then, the aluminum film was exposed to an oxygen amount 0.2 ppm environment under an atmospheric pressure for 5 minutes.

Then, by depositing aluminum (deposition rate=0.4 nm/second) through a vacuum deposition process again with a heart shaped-metal mask, an aluminum film (thickness: 5 nm) having a heart shaped-opening part was laminated on the aluminum film. Then, the aluminum film was exposed to an oxygen amount 0.2 ppm environment under an atmospheric pressure for 5 minutes. Thereby, a first metal film was obtained.

Then, with the metal mask used for the formation of the electron injecting layer used as it is, aluminum was deposited (deposition rate=0.4 nm/second) by a vacuum deposition process. Thereby, a second metal film (thickness: 300 nm) made of aluminum of a 90 mm×90 mm size was formed on the electron injecting layer with the first metal film formed.

The reflectance of the organic EL device of the example 2 was measured. It was 83% in a region with the first metal film facing the organic EL layer side, and it was 96% in a region with the second metal film facing the organic EL layer side. Therefore, a heart shaped-pattern was observed in the organic EL device of the example 2. Moreover, this device was capable of character display by the passive drive.

According to comparison between the example 1 and the example 2, the heart shaped-pattern is recognized further easily in the case of the example 2.

### Example 3

An organic EL device was produced in the same manner as in the example 1 except that the electron injecting layer was formed as follows.

### (Formation of Electron Injecting Layer)

A metal mask having an opening part of a 90 mm×90 mm size on the surface side with the red light emitting layer formed was disposed to face the light emitting area (opening part) of the insulating layer. Then, an electron injecting layer (Alq₃ (thickness: 10 nm)/LiF (thickness: 2 nm)) was formed by depositing an aluminum complex (Alq₃) and lithium fluoride (LiF) (deposition rate=0.1 nm/second) by a vacuum deposition process via the mask.

The reflectance of the organic EL device of the example 3 was measured. It was 88% in a region with the first metal film facing the organic EL layer side, and it was 96% in a region with the second metal film facing the organic EL layer side. Therefore, a heart shaped-pattern was observed in the organic EL device of the example 3. Moreover, this device was capable of character display by the passive drive.

### Example 4

An organic EL device was produced in the same manner as in the example 1 except that the metal electrode layer was formed as follows.

### (Formation of Metal Electrode Layer)

By depositing aluminum (deposition rate=0.4 nm/second) through a vacuum deposition process with a heart shaped-metal mask, a first metal film made of aluminum (thickness: 300 nm) having a heart shaped-opening part was formed on the electron injecting layer.

Then, with the metal mask used for the formation of the electron injecting layer used as it is, gold was deposited (deposition rate=0.4 nm/second) by a vacuum deposition process. Thereby, a second metal film (thickness: 300 nm) made of gold of a 90 mm×90 mm size was formed on the electron injecting layer with the first metal film formed.

In the organic EL device of the example 4, a region with the first metal film facing the organic EL layer side and a region with the second metal film facing the organic EL layer side have different colors of reflected lights so that a heart shaped-pattern was recognized. Moreover, this device was capable of character display by the passive drive.

### Example 5

An organic EL device was produced in the same manner as in the example 1 except that the metal electrode layer was formed as follows.

### (Formation of Metal Electrode Layer)

By depositing aluminum (deposition rate=0.4 nm/second) through a vacuum deposition process with a heart shaped-metal mask, a first metal film made of aluminum (thickness: 300 nm) having a heart shaped-opening part was formed on the electron injecting layer.

Then, with the metal mask used for the formation of the electron injecting layer used as it is, a film of N,N′-bis-(3-methyl phenyl)-N,N′-bis-(phenyl)-benzidine (TPD) was formed by a resistance heat deposition process on the electron injecting layer, with the first metal film formed, for forming a charge transporting protection layer (thickness: 100 nm). Furthermore, an IZO thin film (thickness: 150 nm) was formed on the charge transporting protection layer by a facing target sputtering process for forming a second metal film made of IZO.

In the organic EL device of the example 5, a region with the first metal film facing the organic EL layer side reflects a light, and a region with the second metal film facing the organic EL layer side transmits a light so that so that a heart shaped-pattern was recognized. Moreover, this device was capable of character display by the passive drive.

What is claimed is:

1. An organic electroluminescence device comprising:
a substrate,
a transparent electrode layer formed on the substrate,
an organic electroluminescence layer including a light emitting layer, formed on the transparent electrode layer, and a metal electrode layer including a first metal film and a second metal film, formed on the organic electroluminescence layer,
wherein the metal electrode layer comprises: a first electrode region with the first metal film disposed to face the organic electroluminescence layer side, and a second electrode region with the second metal film disposed to face the organic electroluminescence layer side,
and wherein the first electrode region and the second electrode region have different reflection characteristics, and the first metal film of the first electrode region and the second metal film of the second electrode region contact electrically.

2. The organic electroluminescence device according to claim 1, wherein the first metal film and the second metal film contain a same metal element.

3. The organic electroluminescence device according to claim 2, wherein the metal element is aluminum.

4. The organic electroluminescence device according to claim 1, wherein a reflectance of the first electrode region is lower than a reflectance of the second electrode region.

5. The organic electroluminescence device according to claim 1, wherein the first electrode region and the second electrode region have different colors of reflected lights.

6. The organic electroluminescence device according to claim 1, wherein the first metal film and the second metal film are laminated successively on the organic electroluminescence layer in the first electrode region, and the second metal film is formed on the organic electroluminescence layer without formation of the first metal film in the second electrode region.

7. The organic electroluminescence device according to claim 1, wherein the first metal film and the second metal film are laminated successively on the organic electroluminescence layer in the first electrode region; and the second metal film, the first metal film, and the second metal film are laminated successively on the organic electroluminescence layer in the second electrode region.

8. The organic electroluminescence device according to claim 1, wherein the first metal film is formed on the organic electroluminescence layer in the first electrode region without formation of the second metal film, and the second metal film is formed on the organic electroluminescence layer in the second electrode region without formation of the first metal film.

9. A production method of an organic electroluminescence device comprising a metal electrode layer forming step which further comprises a first metal film forming step and a second metal film forming step, wherein
the first metal film forming step is for forming a first metal film and includes: a first metal film forming layer forming step for forming a first metal film forming layer in a pattern in vacuum on a substrate with a transparent electrode layer and an organic electroluminescence layer including a light emitting layer laminated successively, and an exposing step of exposing the first metal film forming layer to atmosphere including oxygen;
the second metal film forming step is for forming a second metal film in vacuum onto the entire surface of the substrate with the first metal film formed in the pattern; and
the metal electrode layer forming step is for forming a metal electrode layer which comprises: a first electrode region with the first metal film disposed to face the organic electroluminescence layer side, and a second electrode region with the second metal film disposed to face the organic electroluminescence layer side.

10. A production method of an organic electroluminescence device comprising a metal electrode layer forming step which further comprises a first-second metal film forming step, a first metal film forming step, and a second-second metal film forming step, wherein
the first-second metal film forming step is for forming a second metal film in a pattern in vacuum on a substrate with a transparent electrode layer and an organic electroluminescence layer including a light emitting layer laminated successively;
the first metal film forming step is for forming a first metal film and includes a first metal film forming layer forming step of forming a first metal film forming layer in vacuum on the entire surface of the substrate with the second metal film formed, and an exposing step of exposing the first metal film forming layer to atmosphere including oxygen;
the second-second metal film forming step is for forming a second metal film in vacuum on the entire surface of the substrate with the second metal film and the first metal film formed; and
the metal electrode layer forming step is for forming a metal electrode layer which comprises: a first electrode region with the first metal film disposed to face the organic electroluminescence layer side, and a second electrode region with the second metal film disposed to face the organic electroluminescence layer side.

11. The production method of an organic electroluminescence device according to claim 9, wherein the first metal film with a plurality of layers laminated is formed by repeating the first metal film forming layer forming step and the exposing step in the first metal film forming step.

12. The production method of an organic electroluminescence device according to claim 10, wherein the first metal film with a plurality of layers laminated is formed by repeating the first metal film forming layer forming step and the exposing step in the first metal film forming step.

13. The production method of an organic electroluminescence device according to claim 9, wherein a film of a same metal is formed in the first metal film forming step and the second metal film forming step.

14. The production method of an organic electroluminescence device according to claim 10, wherein a film of a same metal is formed in the first metal film forming step and the second metal film forming step.

15. The production method of an organic electroluminescence device according to claim 13, wherein the metal is aluminum.

16. The production method of an organic electroluminescence device according to claim 14, wherein the metal is aluminum.
